(19) United States
(12) Patent Application Publication
(10) Pub. No.: US 2026/0319292 A1
(43) Pub. Date: Oct. 15, 2026

(54) BACKLIGHT STRUCTURE AND DISPLAY DEVICE

(71) Applicants: Asphetek Solution (Chengdu) Ltd., Chengdu (CN); Asphetek Solution Inc., Hsinchu (TW)

(72) Inventors: HUNG-CHIEH CHIN, Hsinchu (TW); CHENG-HONG JIANG, Hsinchu (TW); CHING-LIN LI, Hsinchu (TW); YEN-HENG HUANG, Hsinchu (TW)

(21) Appl. No.: 19/245,840

(22) Filed: Jun. 23, 2025

(30) Foreign Application Priority Data
Apr. 11, 2025 (CN) 202510456401.6

(51) Int. Cl. G02F 1/13357

(52) U.S. Cl. CPC G02F 1/133606; G02F 1/133621; H10H 20/8131; H10H 29/962

(57) ABSTRACT

A backlight structure includes: a plurality of first light-emitting elements, each of the plurality of first light-emitting elements being configured to emit first light and second light; a plurality of second light-emitting elements, each of the plurality of second light-emitting elements being configured to emit third light; and a modulation element configured to modulate the first light, the second light and the third light into illumination light; wherein the first light and the second light are configured to compensate for light intensity of the third light in a first wavelength band, a FWHM of the illumination light at a first wavelength satisfies: 0 nm<FWHM<30 nm, a maximum effective light intensity of the illumination light within the first wavelength band is greater than 5000 cd/m², and the first wavelength is located within the first wavelength band. A display device is also provided.

### FIELD

The subject matter herein generally relates to display field, especially relates to a backlight structure and a display device.

### BACKGROUND

In recent years, light emitting diode (LED) backlight structures are often used in displays. Particularly in Liquid Crystal Display (LCD) devices, a performance of the LED backlight structure directly impacts screen color reproduction and visual experience. Conventional LED backlight structures predominantly employ a single-type light source architecture. However, such single-source architecture struggles to simultaneously achieve high contrast ratio, high brightness, and wide color gamut.

### BRIEF DESCRIPTION OF THE DRAWINGS

Implementations of the present disclosure will now be described, by way of embodiment, with reference to the attached figures, wherein:

FIG. 1 is a schematic structural diagram of a backlight structure according to an embodiment of the present disclosure.

FIG. 2 is a relationship diagram between an effective light intensity and a wavelength of the backlight structure according to the embodiment of the present disclosure.

FIG. 3 is a schematic structural diagram of a backlight structure according to another embodiment of the present disclosure.

FIG. 4 is a schematic structural diagram of a backlight structure according to yet another embodiment of the present disclosure.

FIG. 5 is a schematic structural diagram of a backlight structure according to additional embodiments of the present disclosure.

FIG. 6 is a schematic structural diagram of a first light-emitting element according to an embodiment of the present disclosure.

FIG. 7 is a schematic structural diagram of a first light-emitting element according to another embodiment of the present disclosure.

FIG. 8 is a schematic structural diagram of a display device according to an embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “comprising,” when utilized, means “including, but not necessarily limited to”; it specifically indicates open-ended inclusion or membership in the so-described combination, group, series, and the like.

“Above” means one layer is on top of another layer. In one example, it means one layer is situated directly on top of another layer. In another example, it means one layer is situated over the second layer directly or indirectly with more layers or spacers in between.

When a feature or element is herein referred to as being “on” another feature or element, it can be directly on the other feature or element or intervening features and/or elements may also be present. It will also be understood that, when a feature or element is referred to as being “connected”, to another feature or element, it can be directly connected, attached, or coupled to the other feature or element or an intervening features or elements may be present.

The present embodiment provides a touch panel. This touch panel can be applied to various smart devices that require human-computer interaction, such as displays, smart homes, and terminal communication devices. When the touch panel is applied to the above-mentioned smart devices, it is used to receive touch operations (such as finger touch, stylus touch, etc.), so that the smart device can activate corresponding functions in response to the touch operation.

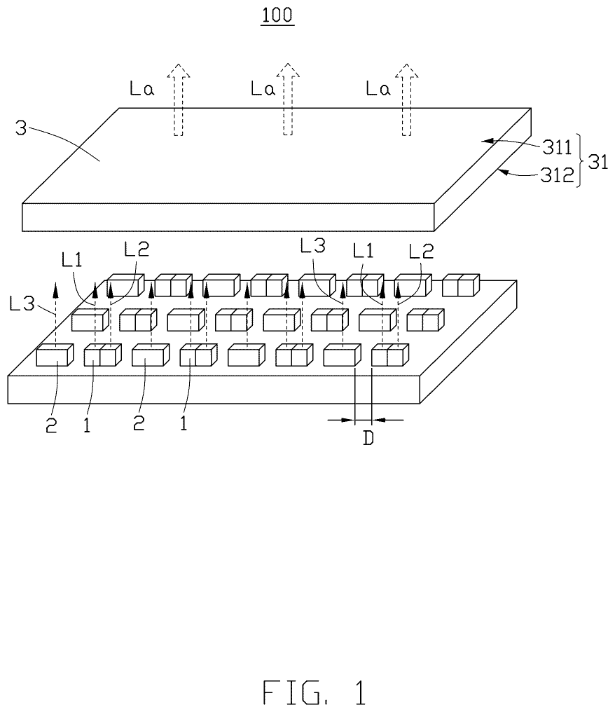

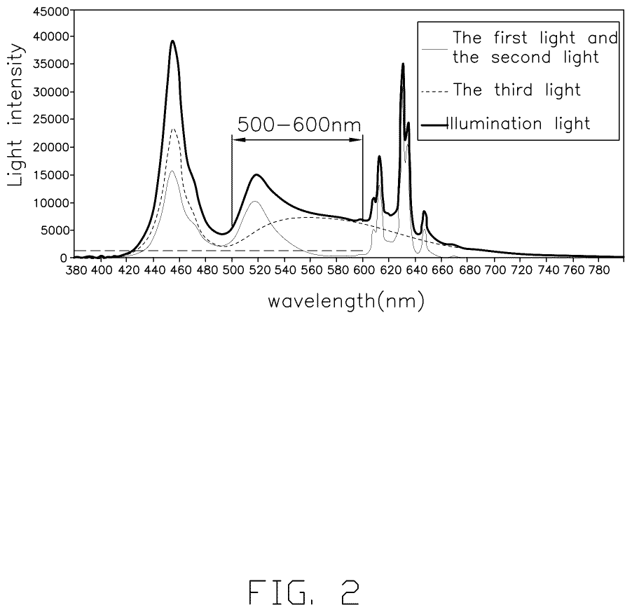

Referring to FIG. 1 and FIG. 2, a backlight structure 100 of a first embodiment includes a plurality of first light emitting units 1, a plurality of second light emitting units 2, and a modulation element 3. Each first light emitting unit 1 is used to emit first light L1 and second light L2. Each second light emitting unit 2 is used to emit third light L3. The modulation element 3 is used to receive and modulate the first light L1, the second light L2, and the third light L3 into illumination light.

A full width at half maximum (FWHM) of the first light L1 and the second light L2 at a first wavelength is smaller than a full width at half maximum (FWHM) of the third light L3 at the first wavelength (the first wavelength is in a first wavelength band). That is, light intensities of the first light L1 and the second light L2 in the first wavelength band have a significant peak. The first light L1 and the second light L2 are used to supplement a light intensity of the third light L3 in the first wavelength band. That is, a monochromaticity of each first light emitting unit 1 in the first wavelength band is better than that of each second light emitting unit 2, so that the first light emitting units 1 can compensate for weak monochromaticity of the second light emitting units 2 in the first wavelength band. That is, the first light emitting units 1 can compensate for color deficiencies of the second light emitting units 2. The light intensities of the first light L1 and the second light L2 also have significant peaks in other wavelength bands (such as wavelength band 600 nm-660 nm shown in FIG. 2). Therefore, except for the first wavelength band, the monochromaticity of each first light emitting unit 1 in the other wavelength bands is better than that of each second light emitting unit 2, so that the first light emitting units 1 can compensate for the weak monochromaticity of the second light emitting units 2 in other wavelength bands, too.

In addition, a luminous brightness of the third light L3 in the first wavelength band is greater than those of the first light L1 and the second light L2 in the first wavelength band, and the third light L3 also has good luminous brightness in other wavelength bands except for the first wavelength band, so that the second light-emitting element 2 can compensate for the low luminous brightness of the first light-emitting element 1, and thus make the illumination light La mixed by the first light L1, the second light L2, and the third light L3 have high luminous brightness and monochromaticity in the first wavelength band. Furthermore, the illumination light La have higher luminous brightness and better monochromaticity in other wavelength bands. The backlight structure 100 of the present disclosure is beneficial for improving color gamut coverage and luminous brightness compares to a conventional backlight structure including a single kind of light-emitting element.

In this embodiment, the first wavelength band can be 500 nm-600 nm. That is, the first wavelength band is a range from green to yellow light of the visible light spectrum. The first wavelength is within the first wavelength band, for example, the first wavelength may be 500 nm, 510 nm, 520 nm, 525 nm, 527 nm, 530 nm, 540 nm, 550 nm, 560 nm, 570 nm, 580 nm, 590 nm or 600 nm. Since the human eye is sensitive to green light (that is, to light with wavelength within the first wavelength band) and the illumination light La has better luminance and better monochromaticity in the first wavelength band, compared with the backlight structure composed of a single light-emitting element, it is conducive to improving the color gamut coverage and luminance, achieving high brightness, high contrast and wide color gamut, and improving a user experience of display devices applying the backlight structure 100.

Specifically, a half-peak full-width (FWHM) of the illumination light La at the first wavelength satisfies: 0 nm<FWHM<30 nm, and a maximum effective light intensity of the illumination light La within the first wavelength band is greater than 5000 cd/m². The FWHM of the illumination light La at the first wavelength can be 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm or 29 nm. The maximum effective light intensity of the illumination light La within the first wavelength band can be 5100 cd/m², 5300 cd/m², 5500 cd/m², 5700 cd/m², 5900 cd/m², 6000 cd/m², 6500 cd/m², 7000 cd/m², 8500 cd/m², 9000 cd/m², 9500 cd/m², 10000 cd/m², 20000 cd/m², 30000 cd/m², or 40000 cd/m². In other embodiments, the first wavelength band can be 400 nm-500 nm or 600 nm-700 nm, which is not limited in the present disclosure.

When the FWHM of the illumination light La at the first wavelength and the maximum effective light intensity of the illumination light La within the first wavelength band satisfy the above relationship, the monochromaticity of the illumination light La in the first wavelength band can be improved, thereby improving a proportion of the illumination light La having a wavelength within the first wavelength band. Compared with the backlight structure composed of a single light-emitting element, the backlight structure 100 of this embodiment is conducive to improving the color gamut coverage and the luminous brightness, thereby facilitating the simultaneous realization of high brightness, high contrast and wide color gamut, and further enhancing the user experience of display devices applying this backlight structure 100.

The backlight structure 100 provided by the embodiments of the present disclosure includes the first light-emitting elements 1, the second light-emitting elements 2 and the modulation element 3. Each first light-emitting element 1 is used to emit the first light L1 and the second light L2, and each second light-emitting element 2 is used to emit the third light L3. The modulation element 3 is used to receive and modulate the first light L1, the second light L2 and the third light L3 into the illumination light La. That is, the first light L1, the second light L2 and the third light L3 are mixed to form the illumination light La. The first light L1 and the second light L2 are used to make up for the light intensity of the third light L3 in the first wavelength band, which can compensate for the color deficiency of the second light-emitting element 2 in the first wavelength band. The FWHM of the illumination light La at the first wavelength satisfies: 0 nm<FWHM<30 nm, which is conducive to improving the color gamut coverage rate, thereby facilitating the realization of a wide color gamut. The maximum effective light intensity of the illumination light La within the first wavelength band is greater than 5000 cd/m² and the first wavelength is located within the first wavelength band, which can enhance the brightness of the illumination light La within the first wavelength band, thereby facilitating the improvement of the contrast of the backlight structure 100 and enabling the simultaneous realization of high brightness, high contrast, and wide color gamut.

In at least one embodiment, the modulation element 3 includes a light diffusion plate 31 including a first light-exiting surface 311 and a first light-entering surface 312 opposite to the first light-exiting surface 311. The first light-exiting surface 311 and the first light-entering surface 312 are approximately rectangular. All the first light-emitting elements 1 and second light-emitting elements 2 are on the first light-entering surface 312. Each first light-emitting element 1 is used to emit the first light L1 and the second light L2 towards the diffusion plate 31, and each second light-emitting element 2 is used to emit the third light L3 towards the diffusion plate 31. The diffusion plate 31 is used to mix and diffuse the first light L1, the second light L2 and the third light L3 into the illumination light La, and the first light-exiting surface 311 is used to emit the illumination light La.

In at least one embodiment, the first light-emitting elements 1 and the second light-emitting elements 2 are arranged in an array including a plurality of rows and a plurality columns. Each row of the array includes multiple first light-emitting elements 1 and multiple second light-emitting elements 2, the first light-emitting elements 1 and second light-emitting elements 2 arranged alternately, maintaining equal pitch between each two adjacent light-emitting elements. In at least one embodiment, each column of the array includes multiple first light-emitting elements 1 and multiple second light-emitting elements 2, the first light-emitting elements 1 and second light-emitting elements 2 arranged alternately, maintaining equal pitch between each two adjacent light-emitting elements.

A total light intensity of the first light L1 and the second light L2 emitted by all the first light-emitting elements 1 is equal to a light intensity of the third light L3 emitted by all the second light-emitting elements 2. All first light-emitting elements 1 has a same light intensity (includes a light intensity of the first and second light), and all second light emitting units 2 has a same light intensity (light intensity of the third light). In the backlight structure 100, a number ratio of the first light-emitting elements 1 and the second light-emitting elements 2 is 1:1.

The illumination light La is generated by the diffusion plate 31 mixing the first light L1, the second light L2, and the third light L3. Since the first light L1 and the second light L2 have a good color gamut coverage rate and the third light L3 has high light intensity, the illumination light La have all advantages of the first light L1, the second light L2, and the third light L3, which is conducive to improving a color gamut coverage rate of the backlight stricture 100 and achieving both high light intensity and wide color gamut.

In at least one embodiment, at least two of the first light-emitting elements 1 have different luminous intensities, at least two of the second light-emitting elements 2 have different luminous intensities, and the number ratio of the first light-emitting elements 1 to the second light-emitting elements 2 in the backlight structure 100 may be other values, such as 1:2 or 1:3, as long as the total light intensity of the first light L1 and the second light L2 emitted by all first light-emitting elements 1 is equal to the light intensity of the third light L3 emitted by all second light-emitting elements 2.

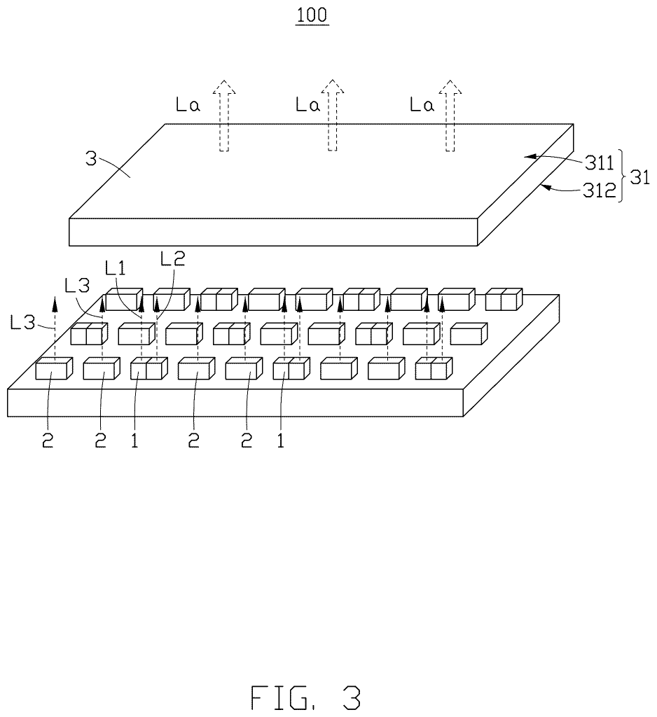

Referring to FIG. 2 and FIG. 3, in at least one embodiment, a total light intensity of the first light L1 emitted by all the first light-emitting elements 1 is equal to a total light intensity of the second light L2 emitted by all the first light-emitting elements 1, and the total light intensity of the first light L1 emitted by all the first light-emitting elements 1 is equal to the total light intensity of the third light L3 emitted by all the second light-emitting elements 2.

In a second embodiment, the number ratio of the first light-emitting elements 1 to the second light-emitting elements 2 in the backlight structure 100 is 2:1. The intensity of the first light L1 emitted by each first light-emitting element 1 is equal to that of the second light L2. And the light intensity of the first light L1 emitted by one first light-emitting element 1 (or the light intensity of the second light L2 emitted by one first light-emitting element 1) is equal to the light intensity of the third light L3 emitted by one second light-emitting element 2. That is, a total light intensity of the first light L1 and the second light L2 emitted by one first light-emitting element 1 is equal to the intensity of the third light L3 emitted by two second light-emitting elements 2. The number of the second light-emitting elements 2 is inversely proportional to an average light intensity of the third light L3 emitted by the second light-emitting elements 2. That is, to ensure that the intensity of the first light L1 emitted from all the first light-emitting elements 1 is equal to that of the third light L3 emitted from all the second light-emitting elements 2, the smaller the light intensity of the third light L3 emitted from a single second light-emitting element 2, the greater the number of second light-emitting elements 2.

In other embodiments, the number ratio of the of the first light-emitting elements 1 to the second light-emitting elements 2 of the backlight structure 100 may be 3:1, 4:1, 1:2, 1:3 or 1:4, which is not limited in this disclosure.

Since the first light L1 emitted by all the first light-emitting elements 1, the second light L2 emitted by all the first light-emitting elements 1, and the third light L3 emitted by all the second light-emitting elements 2 have the same light intensity, and the number of the second light-emitting elements 2 is inversely proportional to the average light intensity of the third light L3 emitted by the second light-emitting elements 2, the light diffuser plate 31 can be used to mix the first light L1, the second light L2 and the third light L3 having the same light intensity.

The first light L1 and the second light L2 have good color gamut coverage and luminance, the third light L3 has a relatively good luminance, thus the illumination light La formed by the diffusion plate 31 mixing the first light L1, the second light L2 and the third light L3 has the advantages of the first light L1, the second light L2 and the third light L3, which is conducive to further improving the brightness and the color gamut coverage rate of the backlight structure 100, making the backlight structure 100 achieving both high brightness and wide color gamut.

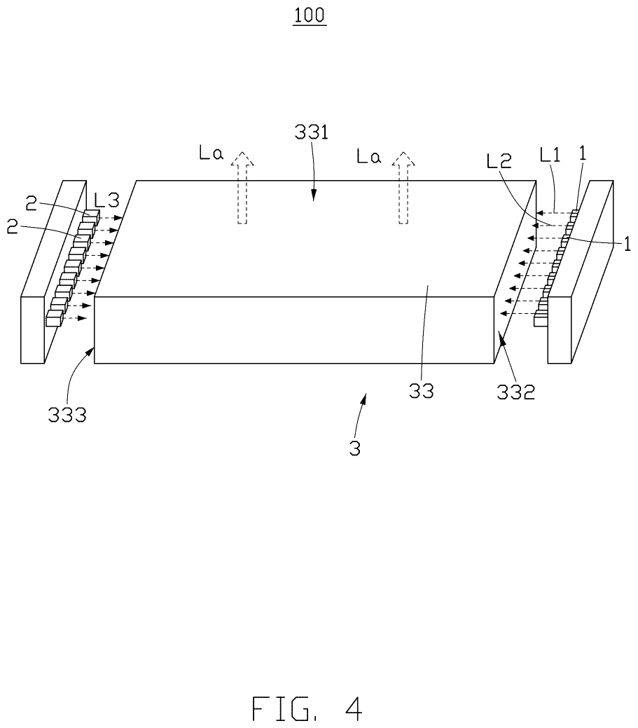

Referring to FIG. 1, FIG. 2 and FIG. 4, in a third embodiment, the modulation element 3 includes a light guide plate 33, the first light-emitting elements 1 are used to emit the first light L1 and the second light L2 towards the light guide plate 33, and the second light-emitting elements 2 are used to emit the third light L3 towards the light guide plate 33. The light guide plate 33 is used to receive and mix the first light L1, the second light L2 and the third light L3 into the illumination light La. The total light intensity of the first light L1 and the second light L2 emitted by all the first light-emitting elements 1 is equal to the total intensity of the third light L3 emitted by all the second light-emitting elements 2.

Since the total light intensity of the first light L1 and the second light L2 emitted by all the first light-emitting elements 1 is equal to the total intensity of the third light L3 emitted by all the second light-emitting elements 2, the light guide plate 33 can be used to mix the first light L1, the second light L2 and the third light L3 having the same light intensity. The first light L1 and the second light L2 have good color gamut coverage and luminance, the third light L3 has a relatively good luminance, thus the illumination light La formed by the light guide plate 33 mixing the first light L1, the second light L2 and the third light L3 has the advantages of the first light L1, the second light L2 and the third light L3, which is conducive to further improving the brightness and the color gamut coverage rate of the backlight structure 100, making the backlight structure 100 achieving both high brightness and wide color gamut.

The light guide plate 33 includes a second light-exiting surface 331, a first side surface 332 and a second side surface 333 opposite to the first side surface 332. The first light-emitting elements 1 are on a side of the light guide plate 33 having the first side surface 332, and the first light-emitting elements 1 are used to emit the first light L1 and the second light L2 towards the first side surface 332. The second light-emitting elements 2 are on a side of the light guide plate 33 having the second side surface 333, and the second light-emitting elements 2 are used to emit the third light L3 towards the second side surface 333. That is, there is only one kind of light-emitting element on each side of the light guide plate 33, which is conducive to reduce processing difficulty and processing cost.

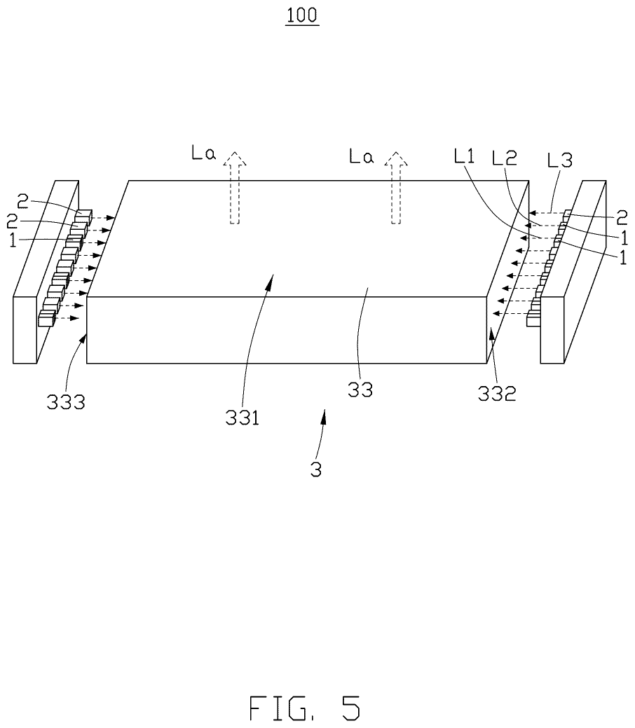

Referring to FIG. 5, in a fourth embodiment, a part of the first light-emitting elements 1 are on the side of the light guide plate 33 having the first side surface 332 and the remaining first light-emitting elements 1 are on the side of the light guide plate 33 having the second side surface 333. A part of the second light-emitting elements 2 are on the side of the light guide plate 33 having the first side surface 332 and the remaining second light-emitting elements 2 are on the side of the light guide plate 33 having the second side surface 333. The first light-emitting elements 1 and the second light-emitting elements 2 on the same side of the light guide plate 33 are alternately arranged.

Since each side of the light guide plate 33 are arranged with two kinds of light-emitting elements, it is conducive to uniformly mixing the first light L1, second light L2 and third light L3 to generate the illumination light La. Furthermore, the mixed illumination light La has the advantages of the first light L1 and second light L2 emitted by the first light-emitting elements 1 and the third light L3 emitted by the second light-emitting elements 2.

Referring to FIG. 1 and FIG. 2, a distance D between each two adjacent light-emitting elements (that is, distance between two first light-emitting elements, distance between two second light-emitting elements, or distance between a first light-emitting element and a second light-emitting element) is within 0.1 mm to 20 mm. The distance D may be 0.1 mm, 0.5 mm, 0.8 mm, 1 mm, 2 mm, 3 mm, 4 mm, 5 mm, 6 mm, 7 mm, 8 mm, 9 mm, 10 mm, 11 mm, 12 mm, 13 mm, 14 mm, 15 mm, 16 mm, 17 mm, 18 mm, 19 mm or 20 mm.

Since the distance D between each two adjacent light-emitting elements is within 0.1 mm to 20 mm, there will be no interference between each two adjacent light-emitting elements, which is conducive to reducing processing difficulty, further conducive to mixing and diffusing the first light L1, the second light L2 and the third light L3 into the illumination light La.

Based on the International Commission on illumination (CIE), a distance between white point coordinates of the first light-emitting element 1 and the second light-emitting element 2 is within −0.05-+0.05. In at least one embodiment, the distance between the white point coordinates in the CIE may be −0.05, −0.04, −0.03, −0.02, −0.01, 0, +0.01, +0.02, +0.03, +0.04, or +0.05. Since the distance between the white point coordinates is within −0.05-+0.05, the first light-emitting elements 1 and the second light-emitting elements 2 have the same color temperature range in color perception, which is conducive to reducing color difference of the backlight structure 100 and making the color difference of the backlight structure 100 lower than the human eye perception threshold. When the above-mentioned backlight structure 100 is applied to a display device, it is beneficial to avoid color spots on the screen and reduce discomfort to the human eye.

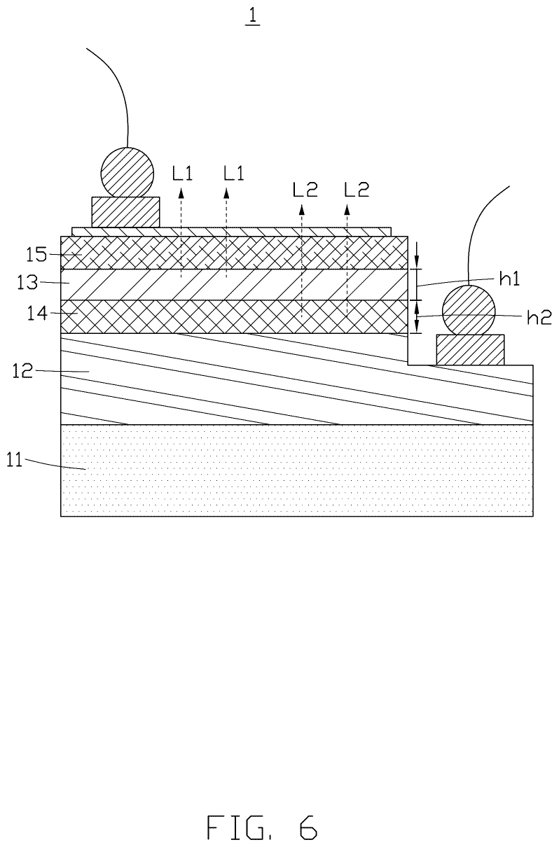

Referring to both FIG. 1 and FIG. 6, in at least one embodiment, each first light-emitting element 1 includes a first substrate layer 11, a first semiconductor layer 12, a first sub light-emitting layer 13, a second sub light-emitting layer 14, and a second semiconductor layer 15. The first semiconductor layer 12, the second sub light-emitting layer 14, the first sub light-emitting layer 13 and the second semiconductor layer 15 are sequentially stacked on the first substrate layer 11. The second sub light-emitting layer 14 is between the first substrate layer 11 and the first sub light-emitting layer 13, and the first semiconductor layer 12 is between the second sub light-emitting layer 14 and the first substrate layer 11.

The first semiconductor layer 12, the second sub emitting layer 14, the first sub emitting layer 13, and the second semiconductor layer 15 are sequentially stacked and arranged on the first substrate layer 11. The second sub emitting layer 14 is arranged between the first sub emitting layer 13 and the first substrate layer 11, and the first semiconductor layer 12 is arranged between the second sub emitting layer 14 and the first substrate layer 11.

The first sub emitting layer 13 is used to emit the first light L1, and the second sub emitting layer 14 is used to emit the second light L2. The material of the first substrate layer 11 can be any one of sapphire, silicon, and silicon carbide. The materials of the first semiconductor layer 12 and the second semiconductor layer 15 can be any one of gallium nitride, gallium arsenide, and aluminum gallium nitride. Specifically, an orthographic projection area of the first sub emitting layer 13 on the first substrate layer 11 is equal to that of the second sub emitting layer 14 on the first substrate layer 11.

A light intensity ratio of the first light L1 emitted from the first sub emitting layer 13 to the second light L2 emitted from the second sub emitting layer 14 ranges from 1:1 to 1:2. The light intensity ratio may be 1:1, 1:1.2, 1:1.4, 1:1.6, 1:1.8, or 1:2.

Since the light intensity ratio ranges from 1:1 to 1:2, each first light-emitting element 1 can emit the first light L1 and the second light L2 with a proper light intensity ratio, which makes the illumination light La including the first light L1 and the second light L2 with a proper light intensity ratio. The backlight structure 100 can improve display effect when applied to a display device 600. Furthermore, the backlight structure 100 can achieve both high brightness and wide color gamut since the first light L1 having high intensity and the second light L2 having good color coverage.

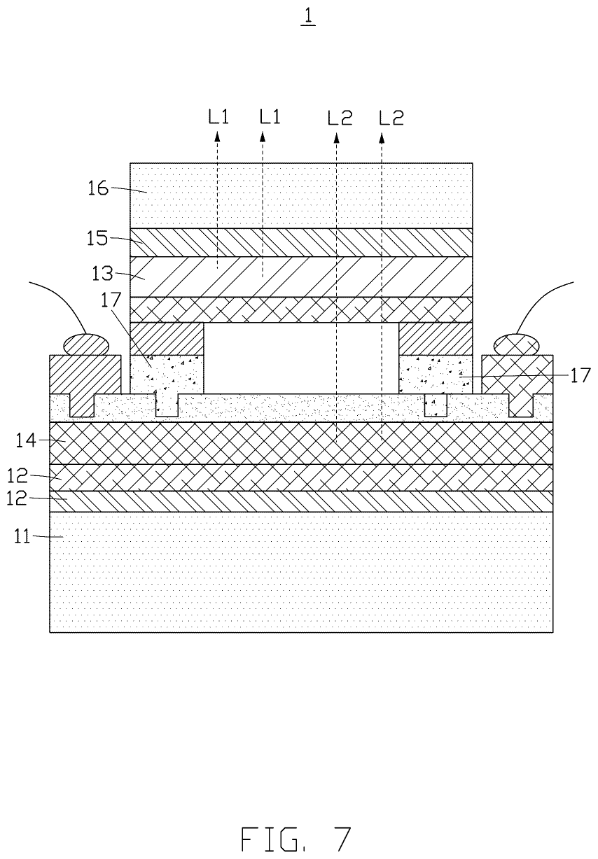

Referring to FIG. 1, FIG. 6 and FIG. 7, in at least one embodiment, each first light-emitting element 1 further includes a second substrate layer 16 and a connecting layer 17. The material of the second substrate layer 16 can be any one of sapphire, silicon and silicon carbide. The first sub-luminescent layer 13 and the second substrate layer 16 are stacked, and the first sub-luminescent layer 13 is on a side of the second sub-luminescent layer 14 away from the first substrate layer 11. A area ratio of an orthographic projection of the first sub-luminescent layer 13 on the first substrate layer 11 to that of the second sub-luminescent layer 14 on the first substrate layer 11 is 1:2. The connecting layer 17 is between the first sub-light-emitting layer 13 and the second sub-light-emitting layer 14 to connect the first sub-light-emitting layer 13 and the second sub-light-emitting layer 14. After the first sub-light-emitting layer 13 and the second substrate layer 16 are formed, they are fixed on a side of the second sub-light-emitting layer 14 away from the first substrate layer 11 through the connecting layer 17, which is conducive to reducing the processing difficulty and further helping to lower the processing cost.

In at least one embodiment, a thickness h1 of the first sub-luminescent layer 13 satisfies: 0 μm<h1<20 μm. The thickness h1 of the first sub-luminescent layer 13 may be 1 μm, 2 μm, 3 μm, 4 μm, 5 μm, 6 μm, 7 μm, 8 μm, 9 μm, 10 μm, 11 μm, 12 μm, 13 μm, 14 μm, 15 μm, 16 μm, 17 μm, 18 μm or 19 μm. A thickness h2 of the second sub-luminescent layer 14 satisfies: 0 μm<h2<20 μm. The thickness h2 of the second sub-luminescent layer 14 may be 1 μm, 2 μm, 3 μm, 4 μm, 5 μm, 6 μm, 7 μm, 8 μm, 9 μm, 10 μm, 11 μm, 12 μm, 13 μm, 14 μm, 15 μm, 16 μm, 17 μm, 18 μm or 19 μm. The first sub-luminescent layer 13 and the second sub-luminescent layer 14 may have a same or different thickness(s), which is not limited in this disclosure.

Since 0 μm<h1<20 μm and 0 μm<h2<20 μm, the first sub-luminescent layer 13 and the second sub-luminescent layer 14 can normally emit light and sizes of the first light-emitting elements 1 is controlled, which is conducive to reducing a volume of the backlight structure 100 including the first light-emitting elements 1.

The backlight structure 100 provided by the embodiments of the present disclosure includes the first light-emitting elements 1, the second light-emitting elements 2 and the modulation element 3. Each first light-emitting element 1 is used to emit the first light L1 and the second light L2, and each second light-emitting element 2 is used to emit the third light L3. The modulation element 3 is used to receive and modulate the first light L1, the second light L2 and the third light L3 into the illumination light La. That is, the first light L1, the second light L2 and the third light L3 are mixed to form the illumination light La. The first light L1 and the second light L2 are used to make up for the light intensity of the third light L3 in the first wavelength band, which can compensate for the color deficiency of the second light-emitting element 2 in the first wavelength band. The FWHM of the illumination light La at the first wavelength satisfies: 0 nm<FWHM<30 nm, which is conducive to improving the color gamut coverage rate, thereby facilitating the realization of a wide color gamut. The maximum effective light intensity of the illumination light La within the first wavelength band is greater than 5000 cd/m² and the first wavelength is located within the first wavelength band, which can enhance the brightness of the illumination light La within the first wavelength band, thereby facilitating the improvement of the contrast of the backlight structure 100 and enabling the simultaneous realization of high brightness, high contrast, and wide color gamut.

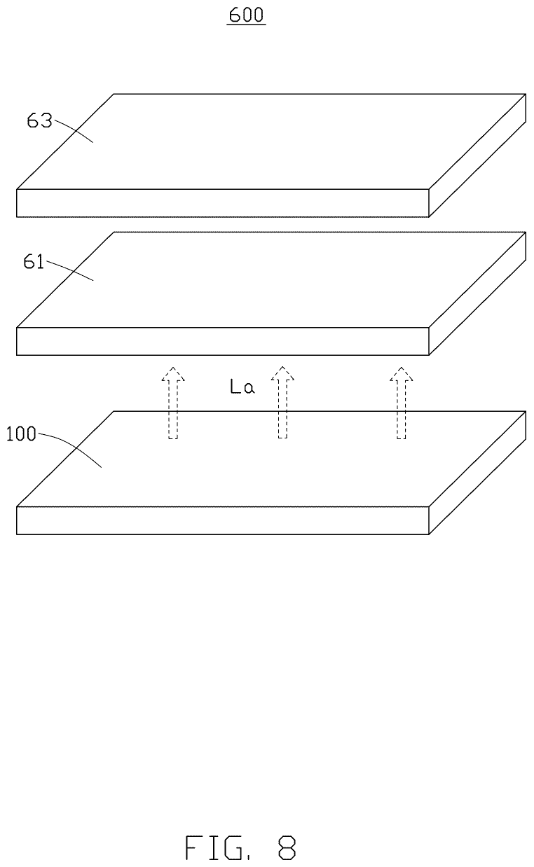

Referring to FIG. 1, FIG. 2 and FIG. 8, the display device 600 of the present disclosure includes the backlight structure 100 as in any of the above embodiments, and the backlight structure 100 is used to emit the illumination light La.

Referring to Table 1, Table 1 shows testing results of a display device applies a backlight structure including a single kind of light-emitting element in contrast to the display device 600 of the present disclosure.

TABLE 1

| | display device applies a | display |
|---|---|---|
| | backlight structure including | device 600 |
| | a single kind of light- | of the |
| | emitting element(display | present |
| | device in the art) | disclosure |
| Light intensity | 489.023 | 605.729 |
| Color space NTSC | 98% | 98.20% |
| Contrast Ratio | 10000:1 | 100000:1 |

Compared with the backlight structure composed of the single kind of light-emitting element, the display device 600 of the present disclosure includes the backlight structure 100 of any of the above embodiments, which has better color gamut coverage and higher luminous brightness. The luminous brightness of the display device 600 is increased by 23.8% compared with the display device in the art, and the NTSC color gamut of the display device 600 is greater than 98%. The contrast ratio (CR) of display device 600 is greater than 100,000:1, which can achieve high brightness, high contrast and wide color gamut, thereby facilitating the improvement of the user experience of display device 600 applying this backlight structure 100.

The display device 600 also includes a display liquid crystal box 61 and a color filter layer 63. The display liquid crystal box 61 is on a light-emitting side of the backlight structure 100 and is between the color filter layer 63 and the backlight structure 100. The display liquid crystal box 61 is used to receive the illumination light La emitted by the diffusion element 3 and is used to control the light transmittance by regulating the arrangement of liquid crystal molecules through an electric field. The color filter layer 63 is configured to selectively transmit light of specific wavelengths. The display liquid crystal box 61 and the color filter layer 63 jointly modulate the illumination light La into image light (not shown in the figure). The display device 600 is used to emit the image light to show images.

The display device 600 provided by the embodiments of the present disclosure includes the backlight structure 100 in any of the above embodiments. The modulation element 3 in the backlight structure 100 is used to modulate the first light L1, the second light L2 and the third light L3 into the illumination light La. The first light L1 and the second light L2 are used to compensate for the light intensity of the third light L3 in the first wavelength band, which can compensate for the color deficiency of the second light-emitting elements 2 in the first wavelength band. The FWHM of the illumination light La at the first wavelength satisfies: 0 nm<FWHM<30 nm. It is conducive to improving the color gamut coverage rate, thereby facilitating the realization of a wide color gamut. The maximum effective light intensity of the illumination light La within the first wavelength band is greater than 5000 cd/m². The first wavelength is in the first wavelength band, which can increase the brightness of the illumination light La in the first wavelength band and is conducive to improving the contrast of the display device 600 using the backlight structure 100. Furthermore, the display device 600 using the backlight structure 100 can achieve high brightness, high contrast and wide color gamut, thereby facilitating the improvement of the user experience.

Finally, it should be noted that the above embodiments are only used to illustrate the technical solution of the present application and not to limit the present application. Although the present application has been described in detail with reference to preferred embodiments, one ordinary skill in the art should understand that the technical solution of the present application can be modified or equivalent replaced without departing from the spirit and scope of the technical solution of the present application.

1. A backlight structure comprising:
a plurality of first light-emitting elements, wherein each of the plurality of first light-emitting elements is configured to emit first light and second light;
a plurality of second light-emitting elements, wherein each of the plurality of second light-emitting elements is configured to emit third light; and
a modulation element configured to receive and modulate the first light, the second light and the third light into illumination light, the modulation element further configured to emit the illumination light,
wherein the first light and the second light are configured to compensate for a light intensity of the third light in a first wavelength band, a half-peak full-width of the illumination light at a first wavelength satisfies: 0 nm<FWHM<30 nm, a maximum effective light intensity of the illumination light within the first wavelength band is greater than 5000 cd/m², and the first wavelength is within the first wavelength band.

2. The backlight structure according to claim 1, wherein the modulation element comprises a diffusion plate comprising a first light-emitting surface and a first light-entering surface opposite each other; and
the plurality of the first light-emitting elements and the plurality of the second light-emitting elements are on a side of the diffusion plate having the first light-entering surface, the diffusion plate is configured to mix and diffuse the first light, the second light and the third light, and the modulation element emits the illumination light transmits out of the diffusion plate from the first light-emitting surface.

3. The backlight structure according to claim 2, wherein the plurality of first light-emitting elements and the plurality of second light-emitting elements are arranged in an array; and
a total light intensity of the first light and the second light emitted by all of the plurality of the first light-emitting elements is equal to a total light intensity of the third light emitted by all of the plurality second light-emitting elements.

4. The backlight structure as according to claim 2, wherein the plurality of first light-emitting elements and the plurality of second light-emitting elements are arranged in an array;
a total light intensity of the first light emitted by all of the plurality of first light-emitting elements is equal to a total light intensity of the second light emitted by all of the plurality of first light-emitting elements; and
the total light intensity of the first light emitted by all of the plurality of first light-emitting elements is equal to a total light intensity of the third light emitted by all of the plurality of second light-emitting elements, a number of the plurality of second light-emitting elements is inversely proportional to an average light intensity of the third light emitted by the plurality of second light-emitting elements.

5. The backlight structure according to claim 1, wherein the modulation element comprises a light guide plate, each of the plurality of first light-emitting elements is configured to emit the first light and the second light towards the light guide plate, and each of the plurality of second light-emitting elements is configured to emit the third light towards the light guide plate; and
a total light intensity of the first light and the second light emitted by all of the plurality of first light-emitting elements is equal to a total light intensity of the third light emitted by all of the plurality of second light-emitting elements.

6. The backlight structure according to claim 5, wherein the light guide plate comprises a first side surface, a second side surface opposite to the first side surface and a second light-emitting surface connected between the first side surface and the second side surface;
the plurality of first light-emitting elements is on a side of the light guide plate having the first side surface, and the plurality of first light-emitting elements are configured to emit the first light and the second light towards the first side surface; and
the plurality of second light-emitting elements are on a side of the light guide plate having the second side surface, and the plurality of second light-emitting elements are configured to emit the third light towards the second side surface.

7. The backlight structure according to claim 5, wherein the light guide plate comprises a first side surface, a second side surface opposite to the first side surface and a second light emitting surface connected between the first side surface and the second side surface; and
a portion of the plurality of first light-emitting elements and a portion of the plurality of second light-emitting elements are on a side of the light guide plate having the first side surface, and a remaining portion of the plurality of first light-emitting elements and a remaining portion of the plurality of second light-emitting elements are on a side of the light guide plate having the second side surface.

8. The backlight structure according to in claim 1, wherein each of the plurality of first light-emitting elements comprises a first sub-light-emitting layer configured to emit the first light and a second sub-light-emitting layer configured to emit the second light; and
a light intensity ratio of the first light emitted by the first sub-light-emitting layer to a second light emitted by the second sub-light-emitting layer is between 1:1 to 1:2.

9. The backlight structure according to claim 8, wherein each of the plurality of first light-emitting elements further comprises a first substrate layer, the second sub-light-emitting layer is stacked between the first sub-light-emitting layer and the first substrate layer; and
an orthographic projection area of the first sub-light-emitting layer on the first substrate layer is equal to an orthographic projection area of the second sub-light-emitting layer on the first substrate layer.

10. The backlight structure according to claim 8, wherein each of the plurality of first light-emitting elements further comprises a first substrate layer, the second sub-light-emitting layer is stacked between the first sub-light-emitting layer and the first substrate layer; and
an area ratio of an orthographic projection of the first sub-light-emitting layer on the first substrate layer to an orthographic projection of the second sub-light-emitting layer on the first substrate layer is 1:2.

11. The backlight structure according to claim 8, wherein a thickness of the first sub-light-emitting layer is h1, and a thickness of the second sub-light-emitting layer is h2, wherein 0 μm<h1<20 μm and 0 μm<h2<20 μm.

12. The backlight structure according to claim 1, wherein a distance between two adjacent light-emitting elements of the plurality of first light-emitting element and the plurality of second light-emitting element ranges from 0.1 mm to 20 mm.

13. The backlight structure according to claim 1, wherein a distance between white point coordinates of the plurality of first light-emitting elements and the second light-emitting elements in the CIE standard color space is within a range of ±0.05.

14. A display device comprising a backlight structure comprising:
a plurality of first light-emitting elements, each of the plurality of first light-emitting elements being configured to emit first light and second light;
a plurality of second light-emitting elements, each of the plurality of second light-emitting elements being configured to emit third light; and
a modulation element configured to receive and modulate the first light, the second light and the third light into illumination light, the modulation element further configured to emit the illumination light, the illumination light being configured to generate image light for displaying images;
wherein the first light and the second light are configured to compensate for a light intensity of the third light in a first wavelength band, a half-peak full-width of the illumination light at a first wavelength satisfies: 0 nm<FWHM<30 nm, a maximum effective light intensity of the illumination light within the first wavelength band is greater than 5000 cd/m², and the first wavelength is within the first wavelength band.
